(19) United States
(12) Patent Application Publication
(10) Pub. No.: US 2008/0202583 A1
(43) Pub. Date: Aug. 28, 2008

(54) DYE-SENSITIZED SOLAR CELL AND METHOD OF MANUFACTURING SAME

(76) Inventor: Wha-Sup Lee, Yongin-si (KR)

Correspondence Address: CHRISTIE, PARKER & HALE, LLP, PO BOX 7068, PASADENA, CA, 91109-7068, US

(21) Appl. No.: 11/966,145

(22) Filed: Dec. 28, 2007

(30) Foreign Application Priority Data
Feb. 28, 2007 (KR) 10-2007-0020501

(51) Int. Cl. H01L 31/0264; H01L 31/04; H01L 31/18

(52) U.S. Cl. 136/262; 136/265; 136/252; 438/63; 257/E31.004

(57) ABSTRACT

A dye-sensitized solar cell including: a first electrode; a light absorption layer on one side of the first electrode; a second electrode facing the light absorption layer on the first electrode; and an electrolyte between the first electrode and the second electrode, wherein the light absorption layer includes: a photosensitive dye adsorbed to a porous membrane, the porous membrane including semiconductor particulates and an -M-O-M- oxide network about the semiconductor particulates, wherein the M is a transition metal.

### CROSS-REFERENCE TO RELATED APPLICATION

This application claims priority to and the benefit of Korean Patent Application No. 10-2007-0020501, filed in the Korean Intellectual Property Office on Feb. 28, 2007, the entire content of which is incorporated herein by reference.

### BACKGROUND OF THE INVENTION

1. Field of the Invention

The present invention relates to a dye-sensitized solar cell and a method of manufacturing the same. More particularly, the present invention relates to a dye-sensitized solar cell that has improved photoelectric efficiency and lifespan due to an increased adsorption amount of a dye and inhibition of recombination of excited electrons and electrons in a ground state of a dye, and a method of manufacturing the same.

2. Description of the Related Art

Diverse research has been carried out in an attempt to develop energy sources that can replace conventional fossil fuels. Particularly, extensive research is underway to find ways for utilizing alternative energy sources, such as wind power, atomic power, and solar power, as substitutes for petroleum resources. Among the alternative energy sources, solar cells use solar energy that is abundant and environmentally friendly, as compared to other energy sources. Since 1983 when an Si solar cell was first produced, solar cells have been progressively developed, and Si solar cells have recently been drawing attention from researchers.

However, practical use of Si solar cells is difficult because the production cost is high and there are difficulties in improving cell efficiency. To overcome the problems, researchers are studying development of a dye-sensitized solar cell that can be produced at a low cost.

Different from the Si solar cell, the dye-sensitized solar cell is an electrochemical solar cell that is mainly composed of photosensitive dye molecules that absorb visible rays and produce electron-hole pairs, and a transition metal oxide that transfers the produced electrons. Among conventional dye-sensitized solar cells is a dye-sensitized solar cell utilizing nano titanium oxide, i.e., anatase.

The dye-sensitized solar cell can be produced at a low cost, and since it uses a transparent electrode, there is an advantage in that it can be applied to external glass walls of a building or a glass greenhouse. However, the dye-sensitized solar cell has a limitation in practical use due to low photoelectric efficiency.

The photoelectric efficiency of a solar cell is in proportion to the quantity of electrons produced from the absorption of solar beams. Thus, to increase the photoelectric efficiency, the quantity of electrons should be increased and/or the electron-hole recombination of produced and excited electrons should be prevented. The quantity of produced electrons can be increased by raising the absorption of solar beams and/or the dye adsorption efficiency.

Particles of an oxide semiconductor should be prepared in a nano-size to increase the dye adsorption efficiency of each unit area, and the reflectivity of a platinum electrode should be increased or a micro-sized oxide semiconductor light scattering agent should be included to increase the absorption of solar beams.

### SUMMARY OF THE INVENTION

An aspect of an embodiment of the present invention is directed toward a dye-sensitized solar cell having improved photoelectric efficiency and lifespan.

Another aspect of an embodiment of the present invention is directed toward a method of manufacturing the dye-sensitized solar cell.

An embodiment of the present invention provides a dye-sensitized solar cell including: a first electrode; a light absorption layer on one side of the first electrode; a second electrode facing the light absorption layer; and an electrolyte between the first electrode and the second electrode, wherein the light absorption layer includes: a photosensitive dye adsorbed to a porous membrane, the porous membrane including semiconductor particulates and an -M-O-M- oxide network surrounding the semiconductor particulates, wherein the M is a transition metal.

The M may be a material from the group consisting of Nb, Zn, Ti, W, and combinations thereof.

The M may be present in an amount ranging from about 0.01 to about 0.09 parts by weight based on 100 parts by weight of the semiconductor particulates.

The semiconductor particulates may include an elementary substance semiconductor, a compound semiconductor, a perovskite compound, and/or mixtures thereof.

The semiconductor particulates may include an oxide including at least one metal selected from the group consisting of Ti, Zr, Sr, Zn, In, Yr, La, V, Mo, W, Sn, Nb, Mg, Al, Y, Sc, Sm, Ga, In, TiSr, and combinations thereof.

The semiconductor particulates may have an average particle diameter ranging from about 5 to about 500 nm.

The semiconductor particulates may be on the first electrode in an amount ranging from about 40 to about 100 mg/mm².

The first electrode may include: a transparent substrate; and a conductive layer on the transparent substrate and including a conductive metal oxide selected from the group consisting of indium tin oxide (ITO), fluorine tin oxide (FTO), ZnO—(Ga₂O₃ or Al₂O₃), a tin-based oxide, antimony tin oxide (ATO), zinc oxide, and combinations thereof.

The transparent substrate may include a plastic substrate.

The plastic substrate may include a material selected from the group consisting of polyethylene terephthalate, polyethylene naphthalate, polycarbonate, polypropylene, polyimide, triacetylcellulose, polyethersulfone, copolymers thereof, and mixtures thereof.

Another embodiment of the present invention provides a method of fabricating the dye-sensitized solar cell, the method including: preparing a porous membrane composition including semiconductor particulates and a metal M-containing precursor, wherein the M is a transition metal; applying the porous membrane composition to a first electrode, and radiating the applied porous membrane composition with UV radiation to form a porous membrane; adsorbing a photosensitized dye on the porous membrane to form a light absorption layer; forming a second electrode on the light absorption layer; and injecting an electrolyte between the first electrode and the second electrode.

The metal M-containing precursor may be a transition metal containing alkoxide or chloride.

The metal M-containing precursor may be an alkoxide or a chloride, and the alkoxide or the cloride may include a metal selected from the group consisting of Nb, Zn, Ti, W, and combinations thereof.

The metal M-containing precursor may include about 0.01 to about 0.09 parts by weight of the metal M based on 100 parts by weight of the semiconductor particulates.

The semiconductor particulates may include a material selected from the group consisting of an elementary substance semiconductor, a compound semiconductor, a perovskite compound, and mixtures thereof.

The semiconductor particulates may include an oxide including a metal selected from the group consisting of Ti, Zr, Sr, Zn, In, Yr, La, V, Mo, W, Sn, Nb, Mg, Al, Y, Sc, Sm, Ga, In, TiSr, and combinations thereof.

The semiconductor particulates may have an average particle diameter ranging from about 5 to about 500 nm.

The first electrode may include: a transparent substrate; and a conductive layer disposed on the transparent substrate and including a conductive metal oxide selected from the group consisting of indium tin oxide (ITO), fluorine tin oxide (FTO), ZnO—(Ga₂O₃ or Al₂O₃), a tin-based oxide, antimony tin oxide (ATO), zinc oxide, and combinations thereof.

The transparent substrate may include a plastic substrate.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic view showing an operation of a conventional dye-sensitized solar cell.

FIG. 2 is a schematic view showing a dye-sensitized solar cell according to an embodiment of the present invention.

FIG. 3 is a flow chart showing a manufacturing process of a dye-sensitized solar cell according to an embodiment of the present invention.

FIG. 4 is a scanning electron microscope photograph of a porous membrane according to Example 2.

FIG. 5 shows mass analysis results of porous membranes according to Comparative Example 1 and Example 2.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

A dye-sensitized solar cell is composed of a porous membrane including nano-sized particles, dyes that adsorb visible light of the sun and excite electrons, an electrolyte, and a transparent electrode, and operates by a principle of photosynthesis.

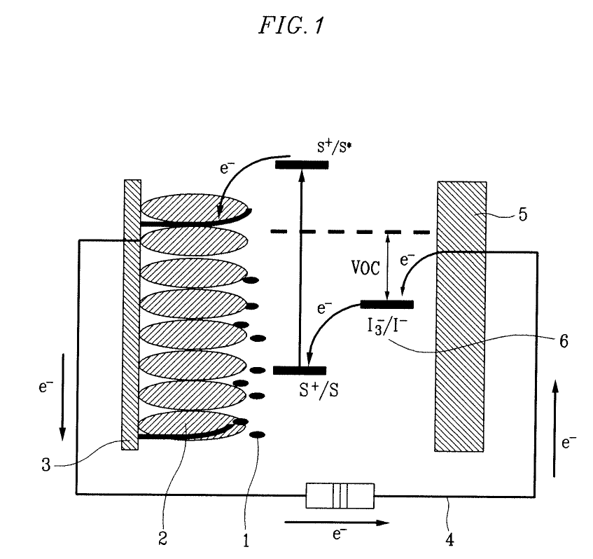

FIG. 1 is a schematic view showing a conventional dye-sensitized solar cell operation.

Referring to FIG. 1, solar beams enter the dye-sensitized solar cell, and dye molecules 1 in a light absorption layer absorb photons. The dye molecules 1 that have absorbed photons are excited from a ground state, which is called electron transfer, to thereby form electron-hole pairs. The excited electrons are injected into a conduction band at the interface of transition metal oxide particles 2, such as titanium oxide. The injected electrons are transferred to a transparent conductor 3 through an interface with the transparent conductor 3, and then are transferred to a Pt counter electrode 5 coupled to the transparent conductor 3, through an external circuit 4. The dye that is oxidized as a result of the electron transfer is reduced by iodine ions (I⁻) of an oxidation-reduction couple 6 in the electrolyte, and oxidized trivalent iodine ions (I₃⁻) are involved in a reduction reaction with electrons that have arrived at the interface of the counter electrode 5 to achieve charge neutrality.

Energy conversion efficiency of the dye-sensitized solar cell is determined by a product of current, voltage, and fill factor. Therefore, current, voltage, and fill factor should be increased in order to improve the energy conversion efficiency. In one embodiment, the voltage can be increased by minimizing recombination through surface modification to result in an increase of electron density of nano-particles in the porous membrane; increasing conduction band energy of nano-particles with respect to a standard hydrogen electrode potential toward a negative value; and/or increasing an oxidation-reduction potential of an oxidation-reduction electrolyte with respect to a standard hydrogen electrode potential toward a positive value.

According to an embodiment of the present invention, an oxide network surrounding semiconductor particulates in a porous membrane is formed to increase dye adsorption amount and also to inhibit recombination (e.g. electron-hole recombination) of excited electrons of a dye with holes and/or inhibit recombination of electrons in a ground state of the dye with holes, resulting in improvement of photoelectric efficiency of a solar cell.

The present invention will be described more detail hereinafter with reference to the accompanying drawings, in which exemplary embodiments of the invention are shown. However, the present invention may be realized in diverse forms, and it is not limited to the embodiments described herein.

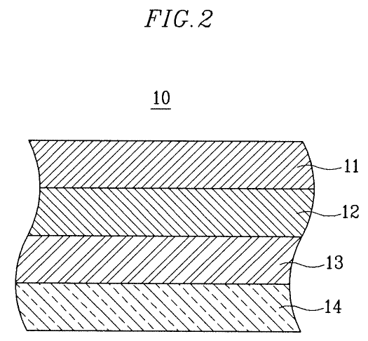

FIG. 2 is a schematic view showing a dye-sensitized solar cell according to an embodiment of the present invention.

Referring to FIG. 2, the dye-sensitized solar cell 10 has a sandwich structure where two plate-type transparent electrodes, which are a first electrode 11 and a second electrode 14, contact each other. One side of the first electrode 11 includes a light absorption layer 12. The light absorption layer 12 is disposed on the surface of the first electrode 11 facing the second electrode 14. A space between the first electrode 11 and the second electrode 14 is filled with an electrolyte 13. The light absorption layer 12 includes a porous membrane, including semiconductor particulates, and dye molecules adsorbed to the porous membrane.

The first electrode (or working electrode or semiconductor electrode) 11 includes a transparent substrate and a conductive layer disposed on the transparent substrate.

The transparent substrate may be formed of any suitable transparent material that transmits external light, such as glass and/or plastics. Non-limiting examples of the plastics may include polyethylene terephthalate (PET), polyethylene naphthalate (PEN), polycarbonate (PC), polypropylene (PP), polyimide (PI), triacetyl cellulose (TAC), polyethersulfone, and copolymers thereof.

The transparent substrate may be doped with a doping material selected from the group consisting of Ti, In, Ga, Al, and combinations thereof.

A conductive layer is disposed on the transparent substrate.

The conductive layer may include a conductive metal oxide selected from the group consisting of indium tin oxide (ITO), fluorine tin oxide (FTO), ZnO—(Ga₂O₃ or Al₂O₃), a tin-based oxide, antimony tin oxide (ATO), zinc oxide, and combinations thereof. SnO₂ or ITO may be appropriate since they have suitable conductivity, transparency, and heat resistance.

The conductive layer may include a single layered metal oxide or a multi-layered metal oxide.

On the first electrode 11, the porous membrane, is formed to include the semiconductor particulates and an -M-O-M- oxide network surrounding the semiconductor particulates, thereby forming the light absorption layer 12, including the photosensitive dye absorbed on the surface of the semiconductor particulates of the porous membrane. Electrons of the photosensitive dye are excited when the dye absorbs visible light.

The porous membrane has uniform nano-pores and an appropriate surface roughness formed by uniformly distributing semiconductor particulates having a very minute and uniform average particle size.

Each semiconductor particulate may be an elementary substance semiconductor, which can be silicon, a compound semiconductor, or a perovskite compound. The semiconductor may be an n-type semiconductor in which electrons of the conduction band become carriers by being optically excited to provide an anode current. Examples of the compound semiconductor include an oxide including a one metal selected from the group consisting of Ti, Zr, Sr, Zn, In, Yr, La, V, Mo, W, Sn, Nb, Mg, Al, Y, Sc, Sm, Ga, In, TiSr, and combinations thereof. According to an embodiment, the compound semiconductor may be TiO₂, SnO₂, ZnO, WO₃, Nb₂O₅, TiSrO₃, or mixtures thereof. According to another embodiment, the compound semiconductor may be anatase TiO₂. The semiconductor is not limited to the above-mentioned materials, and the above-mentioned materials may be used individually or in combination.

The semiconductor particulates may have a large surface area to allow the dye adsorbed onto the surface of the semiconductor particulates to better absorb light. The semiconductor particulate may have an average particle diameter ranging from about 5 to about 500 nm (or 5 to 500 nm). In one embodiment, semiconductor particulates having an average particle diameter of less than 5 nm may be detached from the substrate due to a decrease in close contact with the substrate, and electrons produced from the dye may pass through the naked semiconductor particulates and transfer to an external electrode, which is undesirable. Also, in another embodiment, when the semiconductor particulates have an average particle diameter of over 500 nm, the amount of dye adsorption is small, which is undesirable. According to an embodiment, the semiconductor particulates have an average particle diameter ranging from 10 to 50 nm, considering the manufacturing process and efficiency.

The semiconductor particulates may be loaded on the first electrode 11 in an amount ranging from about 40 to about 100 mg/mm²(or 40 to 100 mg/mm²). According to another embodiment, the semiconductor particulates may be loaded on the first electrode 11 in an amount ranging from 60 to 80 mg/mm². In one embodiment, when the semiconductor particulates are loaded in an amount less than 40 mg/mm², the porous membrane may be too thin, thereby increasing an optical transmission. Thus, it is undesirable because the incident light cannot be utilized effectively. Also, in another embodiment, when the semiconductor particulates are loaded in an amount of over 100 mg/mm², the volume of the porous membrane per unit area may become too large, and the electrons produced by the incident light entering from the outside are combined with holes before they flow to the external electrode. Thus, current cannot be sufficiently generated.

Each semiconductor particulate is surrounded by the -M-O-M- oxide network, where the M is a transition metal. The -M-O-M- oxide network acts as a buffer.

The oxide network is formed by radiating UV during formation of the porous membrane. This increases an adsorption amount of dye and inhibition of recombination of excited electrons and electrons in a ground state of the dye, resulting in improvement of photoelectric efficiency of the solar cell. Such an oxide network shows improved electron transfer properties, compared to an oxide photocathode.

The metal M of the oxide network may be a transition metal selected from the group consisting of Nb, Zn, Ti, W, and combinations thereof.

The M may be present in an amount ranging from about 0.01 to about 0.09 parts by weight (or 0.01 to 0.09 parts by weight) based on 100 parts by weight of the semiconductor particulates. According to an embodiment, the M may be present in an amount ranging from 0.02 to 0.05 parts by weight based on 100 parts by weight of the semiconductor particulates. In one embodiment, when the amount of M in the porous membrane is less than 0.01 parts by weight, the -M-O-M- network is not satisfactory. In another embodiment, when it is more than 0.09 parts by weight, it may inhibit electron transfer.

Dyes are adsorbed on the surface of the semiconductor particulates of the porous membrane to produce excited electrons.

The dye may be a metal composite including a metal selected from the group consisting of aluminum (Al), platinum (Pt), palladium (Pd), europium (Eu), lead (Pb), iridium (Ir), ruthenium (Ru), and combinations thereof. Since ruthenium can form many organic metal composites, ruthenium can be used as the dye. For example, Ru (etc bpy)₂(NCS)₂.2CH₃CN is generally used in the dye-sensitized solar cell. The etc is a (COOEt)₂ or (COOH)₂ reactive group being capable of binding to the surface of the porous membrane (for example, TiO₂). An organic dye such as coumarin, porphyrin, xanthene, riboflavin, triphenyl methane, and so on can also be used. These organic dyes may be used singularly or in a mixture with Ru composites, and they improve visible light adsorption at long wavelengths, resulting in improvement of photoelectric efficiency.

The second electrode (or counter electrode) 14 is disposed facing the first electrode 11 formed with the light absorption layer 12. The second electrode 14 includes a transparent substrate and a transparent electrode facing the first electrode 11, and a catalyst electrode disposed on the transparent substrate.

The transparent substrate may be composed of glass and/or plastic, as in the first electrode 11. Specific examples of the plastic may include polyethylene terephthalate, polyethylene naphthalate, polycarbonate, polypropylene, polyimide, triacetylcellulose, polyethersulfone, and so on.

A transparent electrode is disposed on the transparent substrate.

The transparent electrode may be a transparent material, such as indium tin oxide, fluorine tin oxide, antimony tin oxide, zinc oxide, tin oxide, ZnO—Ga₂O₃, ZnO—Al₂O₃,and so on. The transparent electrode may be composed of a single layered membrane or a multi-layered membrane.

The transparent electrode may be corrugated to increase a light scattering effect. The corrugated surface may have a surface in the shape of as stairs, needles, mesh, scratches, and/or scars. For example, such corrugated surfaces may be formed by scratching the transparent electrode with sandpaper. It can also be formed using other suitable mechanical methods and/or by suitable chemical etching.

The catalyst electrode is disposed on the transparent electrode.

The catalyst electrode activates a redox couple, and includes a conductive material selected from the group consisting of platinum (Pt), gold (Au), ruthenium (Ru), palladium (Pd), rhodium (Rh), iridium (Ir), osmium (Os), carbon (C), WO₃, TiO₂, a conductive polymer, and combinations thereof.

Further, the catalyst electrode facing the first electrode may be porous to increase the surface area so that the catalyst effect is improved. For example, Pt or Au may have a black state (herein, “black state” is referred to as the state in which nothing is supported on the support body), and carbon may have a porous state. Particularly, the platinum black state may be obtained by an anodic oxidation method, a chloroplatinic acid method, and so on. Further, porous carbon may be obtained by sintering a carbon particulate or firing organic polymers.

The transparent substrate of the first electrode 11 is combined (or joined) with the transparent substrate of the second electrode 14 by an adhesive agent. The electrolyte 13 is injected into a hole penetrating the second electrode 14 to be impregnated between the first electrode 11 and the second electrode 14. The electrolyte 13 is uniformly dispersed inside of the porous membrane in the light absorption layer 12.

The electrolyte 13 may be composed of an electrolyte solution that is an iodide/triodide pair. The iodide/triodide pair receives and transfers electrons from the second (or counter) electrode 14 to the dye through an oxidation-reduction reaction. The electrolyte may be a solution prepared by dissolving iodine in acetonitrile, but it is not limited to the iodine acetonitrile solution and may be any substance that has hole conductivity.

Although the present embodiment has been described with a liquid-phase electrolyte 13, a solid-phase electrolyte may also be used within the scope and spirit of the present invention.

A plurality of spacers may be disposed in the space between the first electrode 11 and the second electrode 14 so that the first electrode 11 may be spaced from the second electrode 14 by an interval (that may be predetermined).

The spacers have an insulating property and inhibit an electric short between the first electrode 11 and the second electrode 14.

The spacers may be made of any material suitable for inhibiting an electric short between a semiconductor electrode and a counter electrode. They may also be made in any suitable shape, such as a spherical shape or a stripe shape.

In one embodiment, the dye-sensitized solar cell 10 having the above structure may be fabricated according to the following method that includes preparing a porous membrane composition, including semiconductor particulates and a metal M-containing precursor, where the M is a transition metal; applying the porous membrane composition on a first electrode 11, and radiating UV or firing at a low temperature to form a porous membrane; adsorbing a photosensitized dye on the porous membrane surface to form a light absorption layer 12; and forming a second electrode 14 on the light absorption layer 12, followed by injection of an electrolyte.

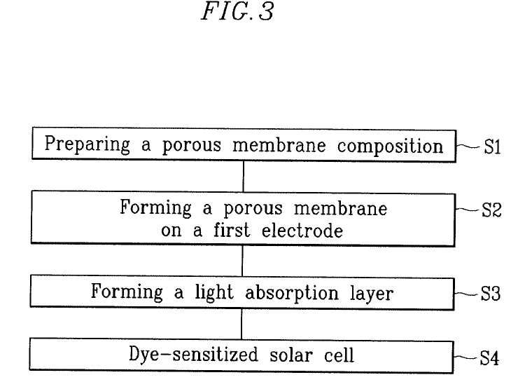

FIG. 3 is a flow chart showing a manufacturing process of a dye-sensitized solar cell according to an embodiment of the present invention.

Referring to FIG. 3, a porous membrane composition, including semiconductor particulates and a metal M-containing precursor is prepared in step S1.

The semiconductor particulates are the same (or substantially the same) as described above.

The metal M-containing precursor may be an alkoxide, a chloride, a hydrate, and so on, which includes a transition metal. According to an embodiment, since dyes have a weak moisture resistance, transition metal-containing alkoxides or chlorides may be appropriate.

Examples of the alkoxide or chloride may include a transition metal selected from the group consisting of Nb, Zn, Ti, W, and combinations thereof. More specific examples of the alkoxide or chloride include titanium (IV) isopropoxide (Ti(O-iPr)₄), Nb₂Cl₅, and mixtures thereof.

The M of the metal M-containing precursor may be present in an amount ranging from about 0.01 to about 0.09 parts by weight (or 0.01 to 0.09 parts by weight) based on 100 parts by weight of the semiconductor particulates. According to an embodiment, the M of the metal M-containing precursor may be present in an amount ranging from 0.02 to 0.05 parts by weight based on 100 parts by weight of the semiconductor particulates. In one embodiment, when the amount of M in the porous membrane is less than 0.01 parts by weight, the -M-O-M- network is not satisfactory. In another embodiment, when it is more than 0.09 parts by weight, it may inhibit electron transfer.

The porous membrane composition may selectively include an additive, such as a binder or a pore-forming polymer.

The binder may include fluoro-based polymers, vinyl-based polymers, acrylate-based polymers, polyalkyleneoxide-based polymers, polyacrylonitrile, polyvinylpyridine, and/or styrene-butadiene rubbers. Examples of the binder include polyvinylidene fluoride (PVDF), a polyhexafluoropropylene-polyvinylidene fluoride copolymer (PVDF/HFP), poly(vinylacetate), polyvinylalcohol, polyethylene oxide, polyvinylpyrrolidone, an alkylated polyethylene oxide, polyvinylether, poly(methylmethacrylate), poly(ethylacrylate), polytetrafluoroethylene, polyvinyl chloride, polyacrylonitrile, polyvinylpyridine, a styrene-butadiene rubber, copolymers thereof, and mixtures thereof.

Here, in one embodiment, a pore-forming polymer that does not leave organic material after heat treatment should be selected. Examples of the polymer include ethylene cellulose (EC), hydroxy propyl cellulose (HPC), polyethylene glycol (PEG), polyethylene oxide (PEO), polyvinyl alcohol (PVA), and polyvinyl pyridone (PVP). Among the polymers, a polymer having an appropriate molecular weight in consideration of coating method and coating conditions is selected. With an appropriate polymer added to the semiconductor particulate layer, a dispersion property, as well as the porosity, can be improved. Further, the layer can be better formed due to an increased viscosity, and adhesiveness to the substrate can be improved.

A solvent may be selected from alcohols such as ethanol, isopropylalcohol, n-propylalcohol, and butanol; and water; dimethylacetamide; dimethylsulfoxide; and/or N-methylpyrrolidone.

In step S2, the porous membrane composition is applied on the first electrode 11 and is then subjected to UV radiation or firing at a low temperature to form a porous membrane.

The first electrode 11 may be formed as described above using a conventional method. For example, the first electrode 11 may be fabricated by forming a conductive layer, including a conductive material, on a transparent substrate using electroplating, a physical vapor deposition (PVD) method, such as sputtering, and/or electron beam deposition.

The porous membrane composition is applied on the first electrode 11 in accordance with a conventional method.

According to an embodiment, the first electrode 11 may be coated with the porous membrane composition by a method selected from the group consisting of screen printing, spray coating, doctor blade coating, gravure coating, dip coating, silk screening, painting, slit die coating, spin coating, roll coating, decalomania coating, and combinations thereof, according to the viscosity of the composition, but the present invention is not limited thereto. According to another embodiment, a doctor blade coating that is capable of coating a porous membrane in a uniform thickness may be used.

The membrane applied on the first electrode 11 is dried, and is then subjected to UV radiation and/or firing at a low temperature.

UV radiation is applied at a power ranging from about 0.5 to about 0.8 W (or 0.5 to 0.8 W). According to an embodiment, the UV radiation may be applied at a power ranging from 0.5 to 0.7 W. In one embodiment, when the UV radiation is applied with a power that is less than 0.5 W, -M-O-M- network formation is not sufficient. In another embodiment, when the UV radiation is applied with a power that is more than 0.8 W, a flexible substrate may be damaged.

That is, a UV radiator for applying the UV radiation may have a detrimental effect on a conductive substrate in the case that the temperature of the radiator increases during radiation application, and therefore its temperature should not be maintained at over about 150° C. for a long time during the application of the UV radiation.

When being fired at a low temperature, the firing is performed at a temperature below about 150° C. According to an embodiment, it is performed at a temperature ranging from about 110 to about 150° C. (or 110 to 150° C.). In one embodiment, when the temperature is over 150° C., a polymer film substrate may be distorted (or damaged).

Through the UV radiation or firing at a low temperature, the metal M of the metal M-containing precursor is bound with oxygen to form an oxide network about the semiconductor particulates.

In step S3, a dye that adsorbs onto the above-prepared porous membrane is deposited by spraying a dispersion solution, including the dye, thereto, coating the porous membrane with the dispersion solution, or impregnating the porous membrane with the dispersion solution.

The adsorption of the dye occurs in 12 hours after the first electrode 11 with the porous membrane is impregnated by the dispersion solution, including the dye, and the adsorption time may be shortened by applying heat thereto. The dye is as described before, and the solvent for dispersing the dye is not limited, but may be acetonitrile, dichloromethane, and/or an alcohol-based solvent.

The dispersion solution, including the dye, may further include organic pigments of diverse colors to improve absorption of long-wavelength visible light and improve cell efficiency.

After the dye layer is deposited, a single-layered light absorption layer 12 may be prepared by rinsing the porous membrane, including the dye, with a solvent.

In step S4, the second electrode 14 is provided and positioned to cover the light absorption layer 12 of the first electrode 11. Then, the electrolyte is injected to fabricate the dye-sensitized solar cell 10.

As described above, the second electrode 14 includes the transparent substrate, the transparent electrode, and the catalyst electrode, and the second electrode 14 may be formed in a suitable fabrication method.

The catalyst electrode may be formed as follows: a catalyst precursor solution (for example, a H₂PtCl₆ solution) dissolved in an organic solvent, such as alcohol, is applied on the transparent electrode, and then heat-treatment is performed under an air or oxygen atmosphere at a high temperature of more than about 400° C. Alternatively, the catalyst electrode may be formed using electroplating, physical vapor deposition (PVD), such as sputtering, and/or electron beam deposition.

The second electrode 14 may be combined (or joined) with the first electrode 11 having the light absorption layer 12 between the second electrode 14 and the first electrode 11, in accordance with a suitable method. In an embodiment, the combining (or joining) is performed by utilizing an adhesive, such as a thermoplastic polymer film, an epoxy resin, or an ultraviolet ray (UV) curing agent; by using melt-fusion with an ultrasonic wave, heat, infrared rays, and/or vibration; and/or by welding.

A hole is formed to penetrate the second electrode 14, and an electrolyte is injected into the space between the first electrode 11 and the second electrode 14 through the hole.

The electrolyte may be the same as described above.

An external part of the hole is sealed with an adhesive agent to thereby fabricate the dye-sensitized solar cell 10.

In the above description, the fabrication method of the solar cell 10 is described using the method including applying the porous membrane composition, including semiconductor particulates and the metal M-containing precursor, followed by UV radiation and/or firing at a low temperature to form the porous membrane. However, the porous membrane may be formed using semiconductor particulates in accordance with a suitable method and then a composition, including a metal M-containing precursor, is applied followed by UV radiation or firing at a low temperature to form the porous membrane.

The following examples illustrate the present invention in more detail. However, the present invention is not limited by these examples.

### EXAMPLE 1

A first electrode was fabricated by forming a conductive layer of tin oxide on a transparent substrate formed of a polyethylene terephthalate polymer at 1 cm×1 cm to have a surface resistance of 10 Ω.

A porous membrane composition was prepared by dispersing 3 g of TiO₂ semiconductor particulates, having an average particle diameter of 20 nm, and 0.03 g of Ti(O-iPr)₄ in 10 ml of alcohol. The first electrode was coated with the porous membrane composition by using a doctor blade, and dried. The dried porous membrane composition was irradiated with 0.5 W of UV, and then rinsed to form a TiO₂ porous membrane having a thickness of 0.010 mm.

Subsequently, the first electrode with the porous membrane was impregnated by a 0.3 mM ruthenium (4,4-dicarboxyl-2,2′-bipyridine)₂(NCS)₂ solution for 24 hours to adsorb the dye to the porous membrane. The porous membrane, with the dye adsorbed thereto, was rinsed with ethanol, and then dried at room temperature to form a light absorption layer on the first electrode.

A second electrode was fabricated by forming a transparent electrode, which was formed of tin oxide and had a surface resistance of 10 Ω, and a catalyst electrode, which was formed of platinum and had a surface resistance of 0.5 Ω, on a transparent substrate formed of a polyethylene terephthalate polymer at 1 cm×1 cm. A hole was formed to penetrate the second electrode by using a drill with a diameter of 0.75 mm.

The first electrode and the second electrode were disposed opposite to each other such that the second electrode could face the porous membrane of the first electrode. Then, a thermoplastic polymer film having a thickness of 60 μm was disposed between the transparent substrate of the first electrode and the transparent substrate of the second electrode. They were compressed at 100° C. for 9 seconds to thereby combine (or join) the first electrode with the second electrode.

An electrolyte was injected through the hole penetrating the second electrode, and the hole was plugged with a thermoplastic resin to thereby complete the fabrication of a solar cell. Herein, the electrolyte was a solution prepared by dissolving 21.928 g of tetrapropylammonium iodide and 1.931 g of iodine (I₂) in a 100 ml mixed solvent of 80 volume % ethylene carbonate and 20 volume % acetonitrile.

### EXAMPLE 2

A first electrode was fabricated by forming a conductive layer of tin oxide on a transparent substrate formed of polyethylene terephthalate polymer at 1 cm×1 cm to have a surface resistance of 10 Ω.

A porous membrane composition was prepared by dispersing 3 g of a TiO₂ semiconductor particulate having an average particle diameter of 20 nm in 10 ml of alcohol. The first electrode was coated with the porous membrane composition by using a doctor blade, and dried. A solution including 5 mmol of Nb₂Cl₅ was applied on the dried porous membrane composition, and dried. Then, the membrane was irradiated with 0.5 W of UV and rinsed to form the TiO₂ porous membrane having a thickness of 0.010 mm.

Subsequently, the first electrode with the porous membrane was impregnated by a 0.3 mM ruthenium (4,4-dicarboxyl-2,2′-bipyridine)₂(NCS)₂ solution for 24 hours to adsorb the dye to the porous membrane. The porous membrane with the dye adsorbed thereto was rinsed with ethanol, and then dried at room temperature to form a light absorption layer on the first electrode.

A second electrode was fabricated by forming a transparent electrode, which was formed of tin oxide and had a surface resistance of 10 Ω, and a catalyst electrode, which was formed of platinum and had a surface resistance of 0.5 Ω, on a transparent substrate. A hole was formed to penetrate the second electrode by using a drill with a diameter of 0.75 mm.

The first electrode and the second electrode were disposed opposite to each other such that the second electrode could face the porous membrane of the first electrode. Then, a thermoplastic polymer film having a thickness of 60 μm was disposed between the transparent substrate of the first electrode and the transparent substrate of the second electrode. They were compressed at 100 ° C. for 9 seconds to thereby combine (or join) the first electrode with the second electrode.

An electrolyte was injected through the hole penetrating the second electrode, and the hole was plugged with a thermoplastic resin to thereby complete the fabrication of a solar cell. Herein, the electrolyte was a solution prepared by dissolving 21.928 g of tetrapropylammonium iodide and 1.931 g of iodine (I₂) in a 100 ml mixed solvent of 80 volume % ethylene carbonate and 20 volume % acetonitrile.

### EXAMPLE 3

A first electrode was fabricated by forming a conductive layer of tin oxide on a transparent substrate formed of polyethylene terephthalate polymer at 1 cm×1 cm to have a surface resistance of 10 Ω.

A porous membrane composition was prepared by dispersing 3 g of a TiO₂ semiconductor particulate having an average particle diameter of 20 nm in 10 ml of alcohol. The first electrode was coated with the porous membrane composition by using a doctor blade, and dried. A solution including 5 mmol of Nb₂Cl₅ was applied on the dried porous membrane composition, and dried. Then, the membrane was fired at a low temperature of 150° C. to form a TiO₂ porous membrane having a thickness of 0.010 mm.

Subsequently, the first electrode with the porous membrane was impregnated by a 0.3 mM ruthenium (4,4-dicarboxyl-2,2′-bipyridine)₂(NCS)₂ solution for 24 hours to adsorb the dye to the porous membrane. The porous membrane with the dye adsorbed thereto was rinsed with ethanol and then dried at room temperature to form a light absorption layer on the first electrode.

A second electrode was fabricated by forming a transparent electrode, which was formed of tin oxide and had a surface resistance of 10 Ω, and a catalyst electrode, which was formed of platinum and had a surface resistance of 0.5 Ω, on a transparent substrate. A hole was formed to penetrate the second electrode by using a drill with a diameter of 0.75 mm.

The first electrode and the second electrode were disposed opposite to each other such that the second electrode could face the porous membrane of the first electrode. Then, a thermoplastic polymer film having a thickness of 60 μm was disposed between the transparent substrate of the first electrode and the transparent substrate of the second electrode. They were compressed at 100° C. for 9 seconds to thereby combine (or join) the first electrode with the second electrode.

An electrolyte was injected through the hole penetrating the second electrode, and the hole was plugged with a thermoplastic resin to thereby complete the fabrication of a solar cell. Herein, the electrolyte was a solution prepared by dissolving 21.928 g of tetrapropylammonium iodide and 1.931 g of iodine (I₂) in a 100 ml mixed solvent of 80 volume % ethylene carbonate and 20 volume % acetonitrile.

### COMPARATIVE EXAMPLE 1

A first electrode was fabricated by forming a conductive layer of tin oxide on a transparent substrate formed of polyethylene terephthalate polymer at 1 cm×1 cm to have a surface resistance of 10 Ω.

A porous membrane composition was prepared by dispersing 3 g of a TiO₂ semiconductor particulate having an average particle diameter of 20 nm in 10 ml of alcohol. The first electrode was coated with the porous membrane composition by using a doctor blade, and dried. Firing was performed at 150° C. for 15 minutes to form a TiO₂ porous membrane having a thickness of 0.01 mm.

Subsequently, the first electrode with the porous membrane was impregnated by a 0.3 mM ruthenium (4,4-dicarboxyl-2,2′-bipyridine)₂(NCS)₂ solution for 24 hours to adsorb the dye to the porous membrane. The porous membrane with the dye adsorbed thereto was rinsed with ethanol, and then dried at room temperature to form a light absorption layer on the first electrode.

A second electrode was fabricated by forming a transparent electrode, which was formed of tin oxide and had a surface resistance of 10 Ω, and a catalyst electrode, which was formed of platinum and had a surface resistance of 0.5 Ω), on a transparent substrate. A hole was formed to penetrate the second electrode by using a drill with a diameter of 0.75 mm.

The first electrode and the second electrode were disposed opposite to each other such that the second electrode could face the porous membrane of the first electrode. Then, a thermoplastic polymer film having a thickness of 60 μm was disposed between the transparent substrate of the first electrode and the transparent substrate of the second electrode. They were compressed at 100° C. for 9 seconds to thereby combine (or join) the first electrode with the second electrode.

An electrolyte was injected through the hole penetrating the second electrode, and the hole was plugged with a thermoplastic resin to thereby complete the fabrication of the solar cell. Herein, the electrolyte was a solution prepared by dissolving 21.928 g of tetrapropylammonium iodide and 1.931 g of iodine (I₂) in a 100 ml mixed solvent of 80 volume % ethylene carbonate and 20 volume % acetonitrile.

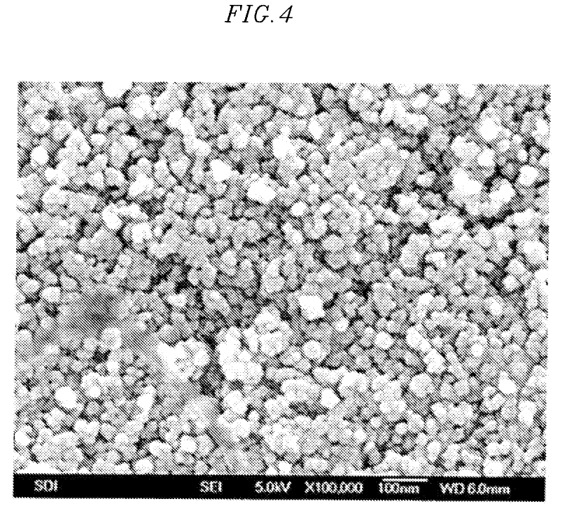

A surface photograph of the porous membrane prepared in Example 2 was taken by a scanning electron microscope, and is shown in FIG. 4.

As shown in FIG. 4, the shape of the semiconductor particulates in the porous membrane is maintained. From these results, it was confirmed that the semiconductor particulates in the porous membrane form pores in the porous membrane without distortion.

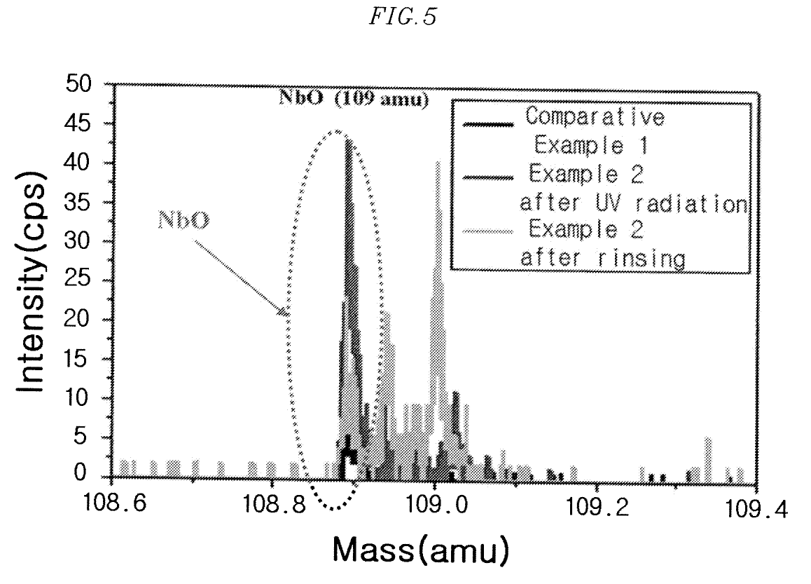

The presence of an oxide network was confirmed using mass analysis of porous membranes according to Comparative Example 1 and Example 2. The results are shown in FIG. 5.

As shown in FIG. 5, NbO oxide peaks are substantially not present in the mass analysis of the porous membrane, according to Comparative Example 1. On the contrary, NbO oxide peaks are shown in the mass analysis of the porous membrane, according to Example 2, after rinsing, as well as after UV radiation. From these results, it is confirmed that an oxide network in the porous membrane, according to Example 2, is formed.

Photocurrent voltages of the dye-sensitized solar cells, according to Examples 1 and 2 and Comparative Example 1, were measured, and the open-circuit voltage (Voc), current density (short-circuit current: Jsc), and fill factor (FF) were calculated based on a curve line of the measured photocurrent voltages. The measurement results are shown in Table 1.

Herein, a xenon lamp, Oriel 01193, was used as a light source, and the solar condition (AM 1.5) of the xenon lamp was corrected by using a standard solar cell (Frunhofer Institute Solare Engeriessysteme, Certificate No. C-ISE369, Type of material: Mono-Si+KG filter).

The fill factor is a value obtained by dividing Vmp×Jmp, where Vmp is a current density and Jmp is a voltage at a maximal electric power voltage, by Voc×Jsc. The photovoltaic efficiency (η) of a solar cell is a conversion efficiency of solar energy to electrical energy, which can be obtained by dividing a solar cell electrical energy (current×voltage×fill factor) by energy per unit area (P_{inc}) as shown the following Equation 1.

η=(Voc·Jsc·FF)/(P_{inc}) (Equation 1)

wherein the P_{inc} is 100 mW/cm²(1 sun).

TABLE 1

| | Jsc | Voc | | Efficiency |
|---|---|---|---|---|
| | (mA/cm²) | (mV) | F.F | (%) |
| Example 1 | 9.59 | 840 | 0.74 | 5.93 |
| Example 2 | 10.41 | 824 | 0.73 | 6.25 |
| Comparative | 8.68 | 757 | 0.71 | 4.63 |
| Example 1 | | | | |

As shown in Table 1, the solar cells of Examples 1 and 2, which included the porous membrane, including an oxide network surrounding the semiconductor particulates, showed improved photoelectric efficiency as compared to the solar cell of Comparative Example 1, which included the porous membrane obtained through heat treatment.

The solar cell according to Example 3 showed a similar result to that of Example 2, as a result of evaluation of cell characteristics.

The dye-sensitized solar cell, according to the present invention, has excellent photoelectric efficiency and lifespan due to an increased adsorption amount of dyes and inhibition of recombination of excited electrons and electrons in a ground state of a dye.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A dye-sensitized solar cell comprising:
a first electrode;
a light absorption layer on one side of the first electrode;
a second electrode facing the light absorption layer; and
an electrolyte between the first electrode and the second electrode,
wherein the light absorption layer comprises: a photosensitive dye adsorbed to a porous membrane, the porous membrane comprising semiconductor particulates and an -M-O-M- oxide network surrounding the semiconductor particulates, wherein the M is a transition metal.

2. The dye-sensitized solar cell of claim 1, wherein the M comprises a material from the group consisting of Nb, Zn, Ti, W, and combinations thereof.

3. The dye-sensitized solar cell of claim 1, wherein the M is present in an amount ranging from about 0.01 to about 0.09 parts by weight based on 100 parts by weight of the semiconductor particulates.

4. The dye-sensitized solar cell of claim 1, wherein the semiconductor particulates comprise an elementary substance semiconductor, a compound semiconductor, and/or a perovskite compound.

5. The dye-sensitized solar cell of claim 1, wherein the semiconductor particulates comprise an oxide comprising a metal selected from the group consisting of Ti, Zr, Sr, Zn, In, Yr, La, V, Mo, W, Sn, Nb, Mg, Al, Y, Sc, Sm, Ga, In, TiSr, and combinations thereof.

6. The dye-sensitized solar cell of claim 1, wherein the semiconductor particulates have an average particle diameter ranging from about 5 to about 500 nm.

7. The dye-sensitized solar cell of claim 1, wherein the semiconductor particulates are on the first electrode in an amount ranging from about 40 to about 100 mg/mm².

8. The dye-sensitized solar cell of claim 1, wherein the first electrode comprises:
a transparent substrate; and
a conductive layer on the transparent substrate and comprising a conductive metal oxide selected from the group consisting of indium tin oxide (ITO), fluorine tin oxide (FTO), ZnO—(Ga₂O₃ or Al₂O₃), a tin-based oxide, antimony tin oxide (ATO), zinc oxide, and combinations thereof.

9. The dye-sensitized solar cell of claim 8, wherein the transparent substrate comprises a plastic substrate.

10. The dye-sensitized solar cell of claim 9, wherein the plastic substrate comprises a material selected from the group consisting of polyethylene terephthalate, polyethylene naphthalate, polycarbonate, polypropylene, polyimide, triacetylcellulose, polyethersulfone, copolymers thereof, and mixtures thereof.

11. A method of fabricating the dye-sensitized solar cell, the method comprising:
preparing a porous membrane composition comprising semiconductor particulates and a metal M-containing precursor, wherein the M is a transition metal;
applying the porous membrane composition to a first electrode, and radiating the applied porous membrane composition with UV radiation to form a porous membrane;
adsorbing a photosensitized dye on the porous membrane to form a light absorption layer;
forming a second electrode on the light absorption layer; and
injecting an electrolyte between the first electrode and the second electrode.

12. The method of claim 11, wherein the metal M-containing precursor is a transition metal containing alkoxide or chloride.

13. The method of claim 11, wherein the metal M-containing precursor is an alkoxide or a chloride, and wherein the alkoxide or the cloride comprises a metal selected from the group consisting of Nb, Zn, Ti, W, and combinations thereof.

14. The method of claim 11, wherein the metal M-containing precursor comprises about 0.01 to about 0.09 parts by weight of the metal M based on 100 parts by weight of the semiconductor particulates.

15. The method of claim 11, wherein the semiconductor particulates comprise a material selected from the group consisting of an elementary substance semiconductor, a compound semiconductor, a perovskite compound, and mixtures thereof.

16. The method of claim 15, wherein the semiconductor particulates comprise an oxide comprising a metal selected from the group consisting of Ti, Zr, Sr, Zn, In, Yr, La, V, Mo, W, Sn, Nb, Mg, Al, Y, Sc, Sm, Ga, In, TiSr, and combinations thereof.

17. The method of claim 11, wherein the semiconductor particulates have an average particle diameter ranging from about 5 to about 500 nm.

18. The method of claim 11, wherein the first electrode comprises:
a transparent substrate; and
a conductive layer disposed on the transparent substrate and comprising a conductive metal oxide selected from the group consisting of indium tin oxide (ITO), fluorine tin oxide (FTO), ZnO—(Ga₂O₃ or Al₂O₃), a tin-based oxide, antimony tin oxide (ATO), zinc oxide, and combinations thereof.

19. The method of claim 18, wherein the transparent substrate comprises a plastic substrate.
